(19) United States
(12) Patent Application Publication
(10) Pub. No.: US 2007/0120616 A1
(43) Pub. Date: May 31, 2007

(54) Multi-band frequency generation method and apparatus

(76) Inventor: Armando J. Gonzalez, Miami, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(21) Appl. No.: 11/288,796

(22) Filed: Nov. 29, 2005

(51) Int. Cl. H03B 5/12

(52) U.S. Cl. 331/179

(57) ABSTRACT

A frequency generation unit (FGU) 160 includes a plurality of selectable voltage controlled oscillators (110) whose output frequencies are chosen in relationship with a predetermined intermediate frequency (IF) and frequency divider value (N) to provide multi-band frequency generation capability in a single communication device. A programmable reference divider (104), phase detector (174) and programmable charge pump (106) take an incoming reference frequency (120) and generate a charge pump output (124). A fixed loop filter (108) filters the charge pump output (124) to generate a control voltage (126) for the selectable VCOs (110). The desired frequency band is selected and enabled using control logic (128).

### TECHNICAL FIELD

This invention relates in general to communication systems and more particularly to the multi-band frequency generation is such systems.

### BACKGROUND

The demand for multi-band communication systems has increased tremendously, particularly in the public safety arena where the interoperability of different communication systems is highly desirable. Fire departments, medical rescue and law enforcement are just a few examples of agencies that can benefit from the ability to communicate across different systems. The ability of a communication device, such as a radio, cell phone, digital assistant or the like, to operate amongst different frequency bands facilitates seamless mobility for the user.

The design of a multi-band communication device is complex as the different operating specifications for each band need to be addressed. In order to provide multi-band operation, circuit designers have typically increased the number of voltage controlled oscillators and provided multiple loop filters. Variations in frequency, tuning sensitivity, acquisition lock time and loop filter bandwidth are examples of operating parameters that need to be addressed in these circuits. Reduction of parts count and utilization of circuit board space are also of paramount importance in a portable multi-band radio design as these affect the cost, size and weight of each device.

Accordingly, a multi-band approach facilitating the issues discussed above is desirable.

### BRIEF DESCRIPTION OF THE DRAWINGS

The features of the present invention, which are believed to be novel, are set forth with particularity in the appended claims. The invention, together with further objects and advantages thereof, may best be understood by reference to the following description, taken in conjunction with the accompanying drawings, in the several figures of which like reference numerals identify like elements, and in which:

FIG. 1 is a block diagram for a multi-band frequency generation circuit formed in accordance with the present invention; and

FIG. 2 is a method for generating an output frequency in accordance with the present invention.

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures, in which like reference numerals are carried forward.

The present invention may be embodied in several forms and manners. The description provided below and the drawings show exemplary embodiments of the invention. Those of skill in the art will appreciate that the invention may be embodied in other forms and manners not shown below. The invention shall have the full scope of the claims and shall not be limited by the embodiments shown below. It is further understood that the use of relational terms, if any, such as first, second, top and bottom, front and rear and the like are used solely for distinguishing one entity or action from another, without necessarily requiring or implying any such actual relationship or order between such entities or actions.

In accordance with the present invention, there is provided herein a frequency generation unit (FGU) having a minimum number of voltage controlled oscillators to satisfy all multi-band requirements in a single communication device. The selection of an appropriate intermediate frequency (IF) and VCO output frequency divider (N) allows for a minimum number of voltage controlled oscillators to selectively cover the desired bands. A programmable charge pump and a programmable reference divider are used to maintain a constant loop bandwidth within the frequency generation unit. The multi-band FGU of the present invention eliminates the need for multiple synthesizer loop filters and eliminates issues with loop filter bandwidth variations and loop filter switching components associated with past circuits.

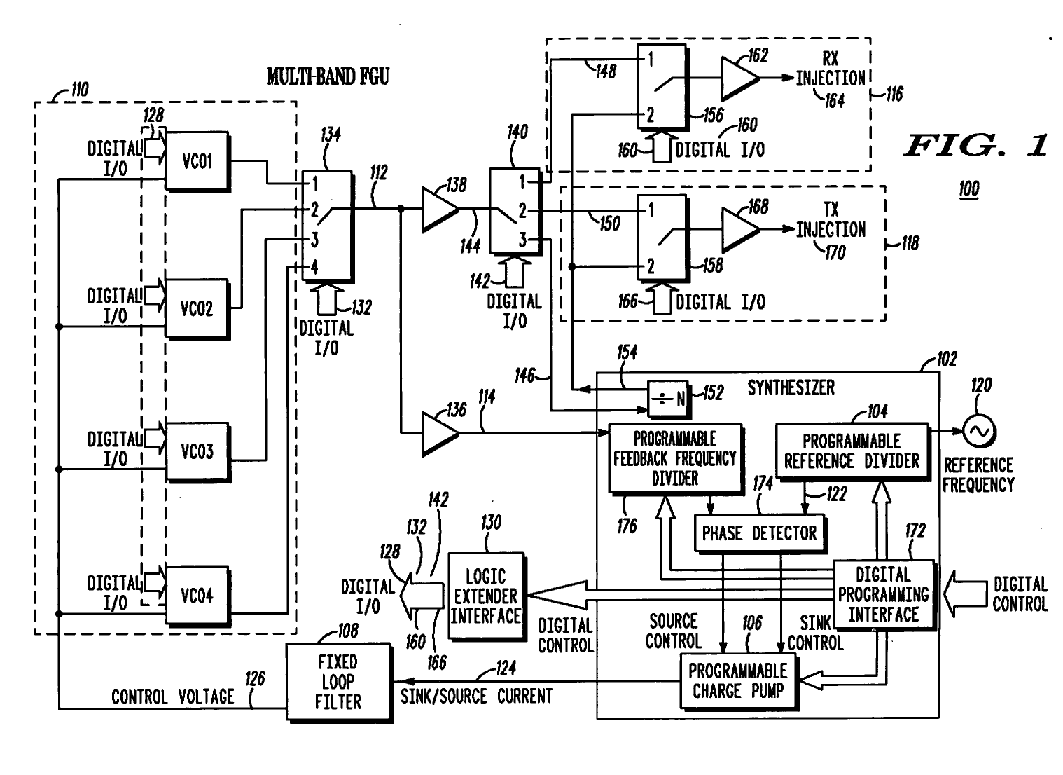

FIG. 1 shows a block diagram of a frequency generation unit (FGU) 100 formed as part of a communication device in accordance with the present invention. FGU 100 comprises a synthesizer 102 having a programmable reference divider 104 and programmable charge pump 106, a fixed loop filter 108, and a plurality of selectable VCOs 110. A selected VCO frequency 112 is fed back to synthesizer 102 along feedback path 114 to programmable feedback frequency divider 176 and phase detector 174 thereby closing the synthesizer loop. The selected VCO frequency 112, with appropriate amplification, can be used for receiver injection via receive (RX) path 116 or for transmit injection via transmit (TX) path 118.

In accordance with the present invention, the VCO frequency bands are chosen and set in conjunction with an appropriate intermediate frequency (IF) and divide-by-N (÷N) VCO output divider 152 such that a minimum number of VCOs can be used to satisfy all desired bands. As an example, for a selected IF of 109.65 MHz and a ÷N of two, all VHF, UHF, 700 MHz and 800 MHz bands can be covered with four VCO modules. For example, from the plurality of VCOs 110, VCO1 can be set for the 700/800 MHz RX bands, VCO2 can be set for the 300/500 MHz and 400/600 MHz UHF TX bands; VCO3 can be set for 200/400 MHz VHF TX band and the 300/599 MHz UHF RX band; and VCO4 can be set for the 200/300 MHz VHF RX band and the 700/800 MHz TX band. Other band combinations can be used based on the selected IF and desired bands of operation. However, this may entail using additional VCO modules. By selecting an appropriate intermediate frequency (IF) and divide-by-N, a minimum number of VCOs can be used to satisfy the desired bands.

Digital programming interface 172 under microprocessor control provides programming capability to the programmable reference divider 104, programmable charge pump 106, programmable feedback frequency divider 176 and a switching logic extender interface 130. Interface 130 generates digital I/Os 128 for selecting the desired VCO and also generates other digital I/Os 132, 142, 160, 166 for controlling a variety of switching circuitry 134, 140, 156, 158 used throughout the FGU 100.

In operation, the programmable reference divider 104 receives and divides a reference frequency 120 to provide a divided reference frequency 122 to the phase detector 174 which provides sink/source controls to the programmable charge pump 106. The programmable charge pump 106 generates a charge pump output 124 which can sink or source current as appropriate. The charge pump output 124 is filtered through a loop filter 108 formed of fixed loop elements (capacitors, resistors, etc.) to produce a control voltage 126. Fixed loop filter 108 maintains a predetermined bandwidth by changing the charge pump current and the reference frequency via programming. The control voltage 126 is used to steer a selected VCO from the plurality of VCOs 110. Control I/O 128 is used to select the desired VCO and desired VCO band of operation within that VCO. For example, digital I/0 128 may consist of a series of logic levels to enable the desired VCO and enable the desired band of operation within the enabled VCO. Each VCO may provide one or more bands of operation as discussed above.

Digital input 132 also controls RF switch 134 for routing the output of the selected VCO back to synthesizer 102 along feedback path 114 with amplification of selected VCO frequency 112 occurring at amplifier 136. The selected VCO output frequency 112 is also amplified at amplifier 138 prior to being injected into either the receive path 116 or the transmit path 118.

Another RF switch 140 under logic control 142 takes amplified signal 144 and routes it to one of three routing paths 146, 148, 150. Routing path 146 divides the signal through the divide-by-N frequency divider 152, preferably integrated within synthesizer 102, to produce divided output signal 154. Divided output signal 154 is forwarded to two routing switches, RX routing switch 156 in the RX path 116 and TX routing switch 158 in the TX path 118. RX routing switch 156 utilizes logic control 160 to route either the undivided output signal from routing path 148 or the divided output signal 154 to amplifier 162 to be used as a RX injection signal 164. TX routing switch 158 utilizes logic control 166 to route either the undivided output signal from path 150 or the divided output signal 154 to amplifier 168 to be used as a TX injection signal 170. The divide-by-N 152 and selection of intermediate frequency (IF) minimizes the number of VCOs required for the FGU 100.

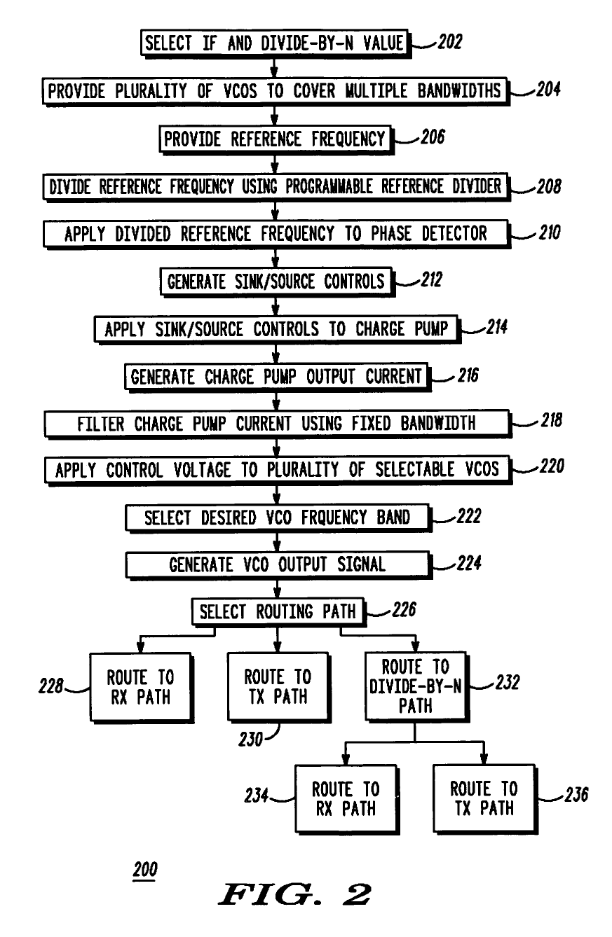

FIG. 2 is a flowchart summarizing the technique of providing multi-band frequency generation in accordance with the present invention. Technique 200 begins at step 202 by selecting an intermediate frequency (IF) 202 and divide-by-N value to provide a plurality of selectable VCOs covering multiple bandwidths at step 204. A reference frequency is provided at step 206 which is divided with a programmable reference divider at step 208. The divided reference frequency is applied to a phase detector at step 210 to generate sink and source controls at step 212 which are applied to a programmable charge pump at step 214. The programmable charge pump generates a charge pump output current (sink/source) at step 216. The charge pump output current is filtered at step 218 via a loop filter formed of fixed elements thereby producing a control voltage. The control voltage is applied to the plurality of selectable VCOs at step 220. By applying the control voltage to the plurality of selectable VCOs at step 220 and selecting a frequency band (via control logic) from the plurality of selectable VCOs at step 222, a VCO output signal is generated at step 224.

Depending on the VCO frequency band selected at step 222, the VCO output signal generated at step 224 is selectively routed at step 226 through either a RX path at step 228, or a TX path at step 230 or is divided by the divide-by-N value at step 232. If routed through the divide-by-N path, then the divide-by-N frequency is then routed to the RX path at step 234 or the TX path at step 236. Signal amplification takes place along the various routing paths as appropriate.

By selecting the appropriate intermediate frequency (IF) in conjunction with selecting a frequency divider N, a minimum number of VCOs are used to satisfy any communication band frequency spectrum bands in a single communication device. Utilizing a programmable charge pump and a programmable reference divider compensates for variations in VCO operating bandwidth and tuning sensitivity. The frequency generation unit formed in accordance with the present invention thus allows for a minimum number of VCOs to achieve multi-band operation. This approach reduces parts count, cost and minimizes printed circuit board real estate thus providing significant advantages to a portable multi-band communication device.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

What is claimed is:

1. A multi-band frequency generation unit, comprising:
a synthesizer including a programmable reference divider, a phase detector and a programmable charge pump, the programmable reference divider dividing a reference frequency and providing a divided reference frequency to the phase detector, the phase detector providing sink/source control to the programmable charge pump, the programmable charge pump generating a charge pump output;
a loop filter having a predetermined bandwidth based on fixed elements, the loop filter filtering the charge pump output and generating a loop filter control voltage output; and
a plurality of selectable voltage controlled oscillators (VCOs) each having output frequencies set in relationship with a predetermined intermediate frequency and frequency divider (N), the plurality of selectable VCOs receiving the control voltage output, the plurality of selectable VCOs selectively providing multi-band frequency generation in response thereto.

2. The multi-band frequency generation unit of claim 1, further comprising: switching logic for selecting a VCO from the plurality of selectable VCOs.

3. The multi-band frequency generation unit of claim 1, wherein the selected VCO output is fed back to the synthesizer and one of: a transmit (TX) injection path and a receive (RX) injection path.

4. A method of generating an output frequency, comprising the steps of:
selecting an intermediate frequency (IF) and a frequency divider value (N);
providing a plurality of selectable VCOs based on the selected IF and frequency divider value (N) to cover multiple bandwidths;
providing a reference frequency;
dividing the reference frequency using a programmable reference divider;
applying the divided frequency to a phase detector to control a programmable charge pump and generate a charge pump output;
filtering the charge pump output using a fixed bandwidth to produce a control voltage;
applying the control voltage to the plurality of selectable VCOs;
selecting a frequency band from the plurality of selectable VCOs; and
generating a VCO output.

5. The method of claim 4, further comprising the steps of:
amplifying the VCO output signal; and
routing the amplified signal to one of: a transmit path and a receive path.

6. The method of claim 4, further comprising the steps of:
dividing the VCO output signal by N to provide a divided-by-N signal; and
routing the divided-by-N signal to one of: the transmit path and the receive path.

7. The method of claim 4, further comprising the step feeding back the VCO output signal to a programmable feedback divider coupled to the phase detector.

8. A communication device, including:
A frequency generation unit (FGU) having a plurality of selectable voltage controlled oscillators whose output frequencies are chosen in relationship with a predetermined intermediate frequency (IF) and divide-by-N VCO output divider value to provide multi-band frequency generation capability in the communication device.

9. The communication device of claim 8, wherein the FGU includes:
a programmable reference divider, a programmable change pump and a fixed loop filter operably coupled to generate a control voltage for the plurality of selectable VCOs.

10. The communication device of claim 8, further comprising control logic to select a frequency band from the plurality of selectable VCOs.

11. The communication device of claim 10, wherein the selectable VCO output is selectably coupled to both transmit and receive paths of the communication device.

12. The communication device of claim 10, wherein the VCO output is selected for use in one of: a transmit path and a receive path.

13. The communication device of claim 12, wherein the VCO output is divided with the divide-by-N value prior to being selected for use in the one of: a transmit path and a receive path.
